(19) United States
(12) Patent Application Publication
(10) Pub. No.: US 2026/0122437 A1
(43) Pub. Date: Apr. 30, 2026

(54) FREQUENCY-BASED COMPENSATION FILTER FOR IN-EAR MONITORS OR HEADPHONES

(71) Applicant: Sound Devices, LLC, Reedsburg, WI (US)

(72) Inventors: Matthew G. Anderson, Madison, WI (US); Steven Popovich, Little Chute, WI (US); Christopher Mittlesteadt, Reedsburg, WI (US)

(73) Assignee: Sound Devices, LLC, Reedsburg, WI (US)

(21) Appl. No.: 19/371,431

(22) Filed: Oct. 28, 2025

Related U.S. Application Data
(60) Provisional application No. 63/712,767, filed on Oct. 28, 2024.

(51) Int. Cl. H04S 3/00; G06F 3/16; H03F 3/68; H04R 5/033; H04R 25/00

(52) U.S. Cl. CPC H04S 3/008; G06F 3/16; H03F 3/68; H04R 5/033; H04R 25/407

(57) ABSTRACT

An in-ear audio transducer such as a single earphone or a pair of earphones produces audio which accounts for frequency detected hearing impairment and auditory masking conditions spanning frequencies expected to be encountered by the user, thereby improving auditory perception without having to increase overall volume as much as in the prior art. The audio transducer(s) communicates with an audio base unit configured to output modified multichannel digital audio data. The in-ear audio transducer element has a processing unit, a plurality of transducer amplifiers and a plurality of acoustic elements.

### CROSS-REFERENCE TO RELATED APPLICATION

The present application claims priority to U.S. Provisional Patent Application No. 63/712,767, filed Oct. 28, 2024, the content of which is incorporated herein by reference in its entirety.

### FIELD OF THE INVENTION

The invention improves the ability for users to perceive audio relayed to them through earpieces or headphones. It does so by selectively amplifying frequency components (using a custom designed frequency response) for an input audio waveform in dependence on the user's hearing and, in some embodiments, the resultant signal-to-noise ratio (SNR) given the presence of background audio disturbances.

### DESCRIPTION OF THE PRIOR ART

Professional stage in-ear monitor systems typically use wireless technology to send the audio mix to the in-ear monitors. The system transmits audio data from a control console via a transmitter (transceiver) to a receiver (transceiver) in an audio base unit (receiver body pack) worn by the performer. Any number of receivers can receive a single audio mix. The transmitters and receivers transfer audio wirelessly via a tuned radio frequency (e.g., tunable in VHF and UHF). The cable for in-ear monitor normally plugs into a 3.5 mm stereo jack on the receiver pack (audio base unit), which is typically clipped onto the belt, guitar strap, clothing of the performer, or placed in a pocket. The receiver pack outputs analog audio signals to the in-ear monitors which are the last stage of the signal path in the system. The in-ear monitors are placed in the external ear canal and seal against the sides of the ear canal.

Universal in-ear monitors typically include a variety of foam and silicone tips. If a universal earpiece does not fit a specific person, they may need to order custom in-ear monitors. Custom-molded in-ear monitors are more comfortable to wear and better isolate ambient noise but can be quite expensive. Depending on the quality of the fit and length of the canal portion of the earpiece, a custom fit in-ear monitor will generally provide somewhere between 25 and 34 dB of noise reduction. This means that loud onstage instruments are less likely to cause hearing damage for onstage musicians wearing in-ear monitors. Impressions for custom in-ear monitors are often taken by an audiologist.

Some performers desire a more natural sound from their in-ear monitors. Passive ambient in-ear monitors have a small hole drilled into the earpiece to allow some natural ambient sound into the ear canal. This can potentially lead to increased sound exposure as it reduces the signal-to-noise ratio (SNR) for the audio mix and causes the musician to increase the volume of the in-ear monitor Active ambient in-ear monitors use external microphones to reproduce the ambient sound in the audio mix.

Many modern audio systems have multiple acoustic output transducers (often times referred to as “speakers”) that work collectively in order to efficiently convert electrical information to a physical waveform that is clearly perceived (heard) by a user (listener). For example, miniaturized headphones and even earbuds often rely on multiple acoustic output transducers, where a smaller transducer (speaker) provides more effective sound reproduction at higher frequencies and a larger transducer (speaker) provides effective sound reproduction at lower frequency sounds in the ear canal of a listener. An example prior art application of this technique is presented by U.S. Pat. No. 8,311,259 where an earphone (or earbud) is configured to fit within a user's auditory canal and contains multiple balanced armature transducers connected to the output of a frequency divider network (labelled as item 107 in FIGS. 1 through 4 of the '259 patent). Some challenges posed by this approach include the need to house a frequency divider network and the fact that if implemented in hardware, it may be difficult (or impossible) to reconfigure based on the customized preferences of a user while in operation.

As mentioned, earpieces (or earbuds) are commonly used by musicians and performers as a means of auditory feedback with regard to the sound they are producing oftentimes along with of one or more other member of their band. Historically, legacy hearing aids and custom molded earphones were adapted to this role. Also as mentioned above, given the high sound levels that are typically present on stage, the use of earpieces allowed for a reduction in the risk of hearing loss to users, since they could block some of the ambient noise, while reproducing the desired feedback at a lower (safer) level. A common problem associated with the use of earpieces involves finding the optimal setting for in-ear sound levels that maximize intelligibility, but without introducing a risk of incurring hearing loss to the user. The fact that many users may themselves already be experiencing some form of hearing loss complicates the ideal settings for such devices. In many instances, preferred device settings may be obtained empirically with a user providing feedback to a sound engineer in control of these settings until a satisfactory sound reproduction has been found. In addition to being time consuming and in many cases somewhat arbitrary (depending on mood, time of day, etc.), this mode of device configuration suffers from the risk that many users may not even themselves be aware that they have sustained hearing loss over the years, leading to settings that may be higher than desired for safety reasons. Of course, restricting a device to a set of conservative settings for sound levels may provide protection for users against hearing loss, but at the same time this may not reliably provide a sufficient SNR for them to be able to judge performance based on the auditory feedback provided.

Some prior art in-ear monitors have been designed with the goal reducing hearing fatigue and reducing the risk of hearing loss. For example, U.S. Pat. No. 10,667,067 B2 entitled “Earguard Monitoring System” by Steven Wayne Goldstein., issuing May 26, 2020, describes the use of a microphone on an in-ear transducer to monitor loudness in the ear canal. An alert is provided if risk is present for either hearing damage or hearing fatigue over time. The Goldstein '067 patent also describes modifying the audio signal presented to the user in response to an audiogram that characterizes a user's hearing sensitivity to compensate for the hearing loss that may be a function over frequency. While methods such as this may help improve intelligibility for audio content presented to a hearing-impaired user, the reality for in-ear monitoring systems is complicated by fact that they are used in environments that possess significant levels of background noise or disturbances which may reduce the intelligibility of audio content presented to the user. In realistic applications, intelligibility is limited by both the hearing ability for the user and auditory masking (clutter effect) caused by other audio disturbances. In order for in-ear-monitors to offer optimum practical benefit, a user must be provided with audio levels sufficient for intelligibility that at the same time do not fatigue or damage hearing as a result of use. Intelligibility, hearing damage and fatigue are functions of signal to noise ratio (SNR) and all vary on a case-by-case basis from one user to the next and furthermore depend on the given operating environment in which they work. A common problem with unregulated gain adjustments is that users are prone to inadvertently set in-ear volume levels too high, resulting in hearing fatigue and even (permanent) cumulative hearing loss for some users. It is an object of the invention to address these issues, which are exacerbated during loud on-stage musical performances.

### SUMMARY OF THE INVENTION

The invention can be implemented in an in-ear-monitoring system used by musicians, or for audio or speech played on earphones or headphones for listening purposes. The invention provides frequency dependent amplification of sound levels to the earpieces and facilitates intelligibility given ambient masking clutter (while also minimizing hearing damage and/or fatigue). The frequency response of the compensation filters is customized for frequency-based hearing ability of each ear based on a series of tests and audiogram data. In order to maximize effectiveness, the testing is carried out in acoustic environments in which the user is expected to experience, and the multiple sets of filter coefficients for the respective acoustic environments and expected auditory masking are saved and able to be retrieved and implemented when the user changes acoustic environments.

The exemplary embodiment of the invention is implemented in a multichannel audio system having a right side in-ear monitor and a left side in-ear monitor of the type used by musical performers, although as mentioned the invention can be implemented with headphones, or even in earbuds or headphones used for listening enjoyment. A significant portion of our population already suffers from some degree of hearing loss-especially in young people. When such people custom tune earpieces or earbuds for their individual use, the temptation remains to provide increasing sound levels to improve their perceptions, that in many cases may end up generating sound levels in their ears that will cause a further accumulation of hearing loss.

In accordance with the invention, the audio transducer element (e.g. in-ear monitor, earbud or earcup in headphones) for each ear has a digital processing unit such as an FPGA, a plurality of analog signal amplifiers and a plurality of speakers. The speakers would typically be two or three speakers of different sizes and designed to output sound over different frequency ranges. The system also has an audio base unit, such as a receiver body pack, that electronically communicates with the right-side audio transducer element for the user's right ear and the left-side audio transducer element for the user's left ear. The receiver body pack preferably has an RF transceiver which communicates with an RF transceiver on a control console or other audio equipment operated, programed or monitored by a sound engineer

Some aspects of this invention can be implemented with wireless communication between the audio base unit and the earpieces, which may be desirable in systems where the audio base unit is a smartphone, computer or similar device streaming music to the user. In the exemplary embodiment, however, digital data is transmitted bidirectionally over a single active line in a bidirectional cable as time-division multiplexed serial data words.

A right-side compensation filter element for the right ear modifies multichannel audio data to drive the speakers in the right-side transducer element in order to account for frequency detected hearing impairment in the right ear and auditory masking conditions in selected acoustic environments expected to be potentially experienced by the user. There is also a left-side compensation filter element for the left ear that modifies multichannel audio data to drive the speakers in the left-side transducer element in order to account for frequency detected hearing impairment in the left ear and auditory masking in selected acoustic environments expected to be potentially experienced by the user. The compensation filter elements are FIR filters or IIR filters. In one embodiment, each compensation filter element contains a series of digital filters having a bandpass filtering stage and a gain stage. The coefficients for the left-side and the right-side compensation filter elements are in general different. The compensation filters can be implemented on the audio base unit or in the digital processors on the in-ear monitors or earbuds. The audio base unit is configured to output multichannel digital audio data, before or after the audio data is modified by the right-side compensation filter element and the left-side compensation filter element, and the speakers in the right-side audio transducer element are driven by multichannel digital audio data modified by the right-side compensation filter element and the speakers in the left-side audio transducer element are driven by multichannel digital audio data modified by the left-side compensation filter element.

In the exemplary embodiment, the coefficients for the right-side compensation filter element and the left-side compensation filter element are stored in non-volatile memory on the right-side in-ear monitor or the left-side in-ear monitor or both. In this way, a musician can save the coefficients on their personalized set of in-ear monitors. It is contemplated the coefficients for the right-side compensation filter element be saved in EEPROM on the right-side in-ear monitor and that the coefficients for the left-side compensation filter element be saved in EEPROM on the left-side in-ear monitor.

Alternatively, the coefficients for the right-side compensation filter element and left-side compensation filter element can be located on the audio base unit, which may be desirable when implementing the invention, e.g., using a smartphone and earbuds for casual listening. The audio base unit desirably has software that implements a test-tone generator, a volume control for the test tone generator, and a spectrogram database for storing hearing test data taken with the test-tone generator. The compensation filter elements are derived from the test-tone data stored in the spectrogram database. During testing, hearing is tested at different frequencies under several different acoustic conditions in order to account for auditory masking in the various acoustic conditions and at the different audio frequencies. The goal is to conduct the tests with auditory masking conditions in which user expects to be using the in-ear monitor or earbuds.

The invention implements digital signal processing, and the earbuds or in-ear monitors need to have suitable digital processing capabilities (e.g. FPGA, DAC circuitry, EEPROM). For many applications, including live music performances, it is important that DC power be provided to the in-ear monitors or earbuds since battery life may not be adequate to support the amount of digital signal processing required. Accordingly, it is desired to use a bidirectional connecting cable to connect the right-side transducer element (in-ear monitor) and the left-side transducer element (in-ear monitor) to a port the audio base unit, as disclosed in Applicant's U.S. patent application Ser. No. 18/900,687, entitled “Bidirectional Multi-Channel Audio Link for Transducers,” filed on Sep. 28, 2024, by Matthew Anderson and Francois Morin, and assigned to the Assignee of the present application. The bidirectional connecting cable has an active line and a ground line, and data is transmitted bidirectionally over the active line as time-division multiplexed serial data words. DC power is also transmitted over the active line from the audio base unit (e.g. receiver body pack) to the in-ear monitor/earbud. The internal digital processor in each in-ear monitor/earbud de-multiplexes multichannel digital audio data and non-audio data transmitted to the respective in-ear monitor and outputs separate digital audio signals for each speaker on the respective in-ear monitor/earbud, which is then converter to analog and amplified to drive the respective speaker on the in-ear monitor/earbud.

In the exemplary embodiment of the invention, each in-ear monitor or earbud has an exterior housing, and an in-ear plug housing that is configured to be placed with the acoustic output port in the ear canal of the user. A first acoustic chamber extends from the first speaker in the exterior housing into the in-ear plug housing and a second acoustic chamber extends from the second speaker in the exterior housing into the in-ear plug housing. The microphone is in or adjacent to the acoustic output port of the in-ear plug housing and generates a microphone signal that is processed and transmitted to the audio base unit. The microphone signal represents the sound pressure level in the ear canal and/or can be used to detect the user's voice. The voice commands can be implemented by a sound engineer and by voice recognition software. Desirably, the user is able to change compensation filter elements using voice commands and select one that is most suitable for each ear.

Other features and advantages of the invention may be apparent to those skilled in the art upon reviewing the following drawings and description thereof.

### BRIEF DESCRIPTION OF THE DRAWINGS

FIG. 1 shows an in-ear audio monitoring system using bidirectional links in accordance with an exemplary embodiment of the invention.

FIG. 2A shows components of an exemplary embodiment for the invention, namely an in-ear monitor including multiple acoustic output transducers (speakers) for improved sound reproduction.

FIG. 2B contains a detailed illustration of the transducer processing unit 400 in the in-ear monitor of FIG. 2A according to the exemplary embodiment of the invention.

FIG. 3A illustrates an audio base unit (e.g. receiver body pack) configured in accordance with the exemplary embodiment for the invention.

FIG. 3B provides a functional diagram of compensation filtering and volume control incorporated into block 201 (FPGA, DSP or standard microprocessor for digital audio processing) of FIG. 3A in accordance with the exemplary embodiment for the invention.

FIG. 4A illustrates an example timing diagram of bidirectional serial communications achieved by applying time-division-multiplexing (TDM) toggling when two half duplex signaling components are located on opposite ends of a communications link. The time period shown corresponds to one sample period for the digital audio data.

FIG. 4B is a timing diagram similar to FIG. 4A modified to describe serial communication using time-division multiplexing (TDM) over the active line in the bidirectional link in a system having a right in-ear monitor and a left in-ear monitor.

FIG. 5 provides an example audiogram used to characterize hearing sensitivity and corresponding hearing loss based on hearing tests performed using the right and left ears of a human test subject referred to as “person-A”.

FIG. 6 illustrates a typical masking effect that may be expected due to the presence of a masking tone at frequencies near that for the masking tone. FIG. 6 further illustrates how additional tones located near the masking tone may be rendered inaudible due to the auditory masking effect in the human auditory system.

FIG. 7 shows example compensation filters that may be derived from data contained in the audiogram of FIG. 6 according to the exemplary embodiment of the invention.

FIGS. 8A through 8E provide data in support of example designs for an FIR compensating filter meeting the design criterion of FIG. 7 according to a simplified example.

FIG. 9 provides a block diagram illustrating construction for a hearing level compensation filter according to a more advanced example.

### DETAILED DESCRIPTION OF THE EXEMPLARY EMBODIMENT OF THE INVENTION

The invention described in this disclosure further fulfills the objectives of protecting against hearing fatigue or hearing loss risk by providing an in-situ hearing test where a user may measure their combined hearing deficit due to personal hearing loss while being coupled with any auditory masking effects that are imposed as a result of a desired operating environment.

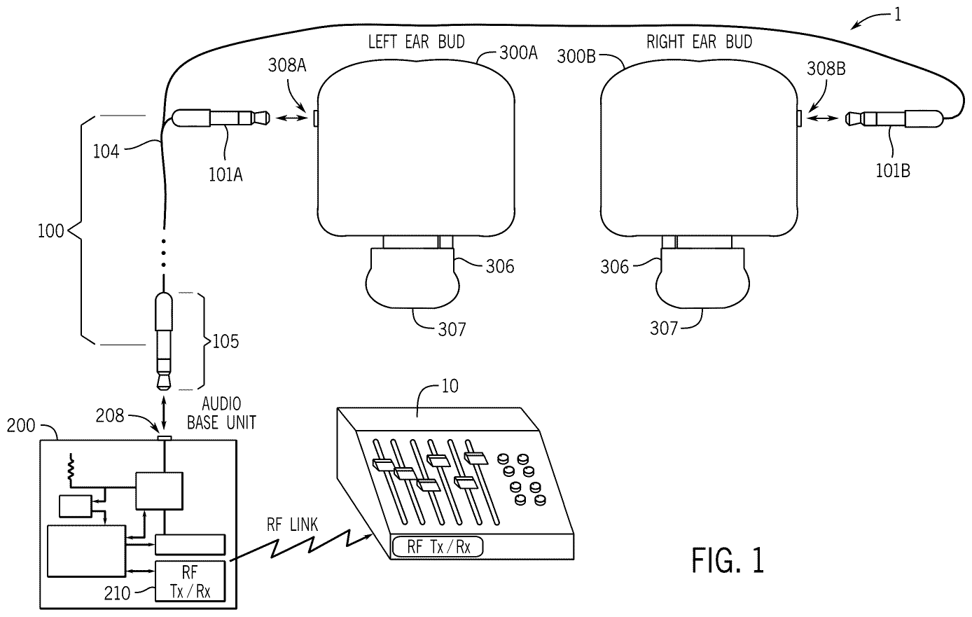

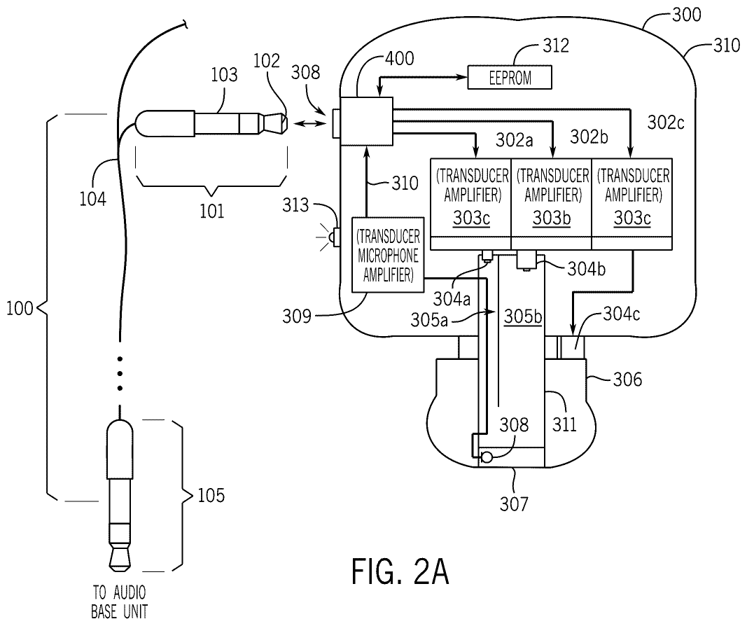

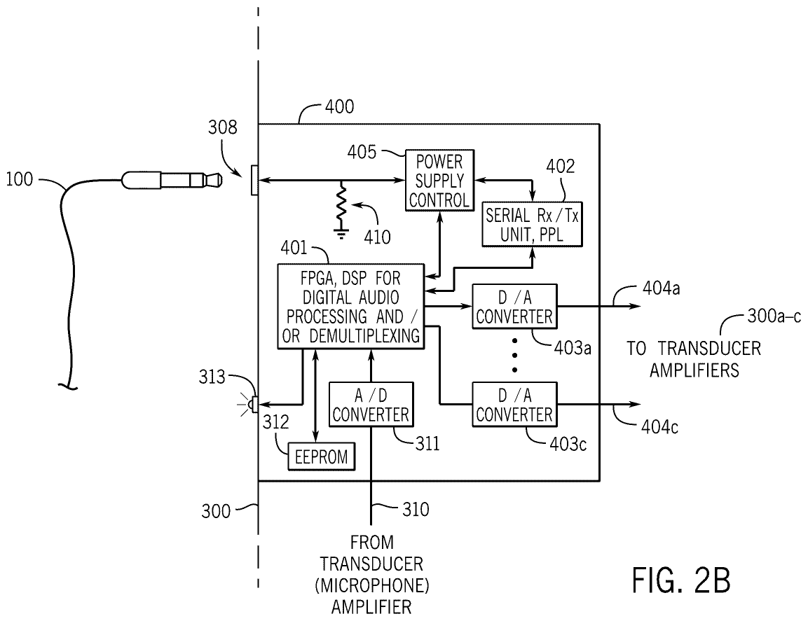

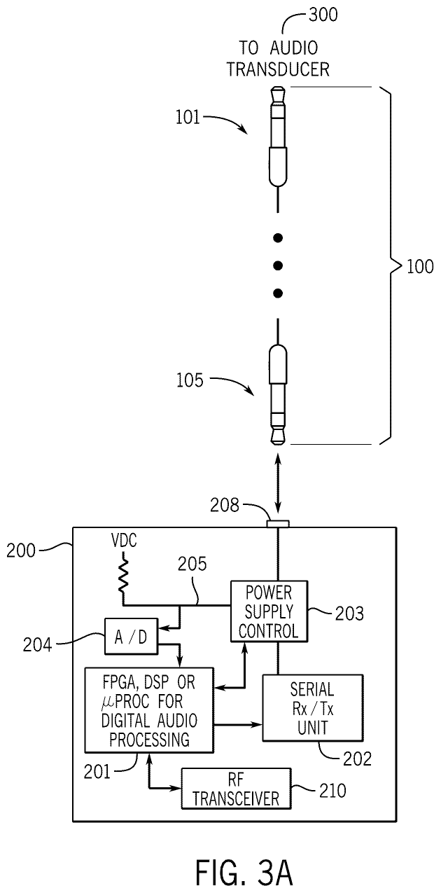

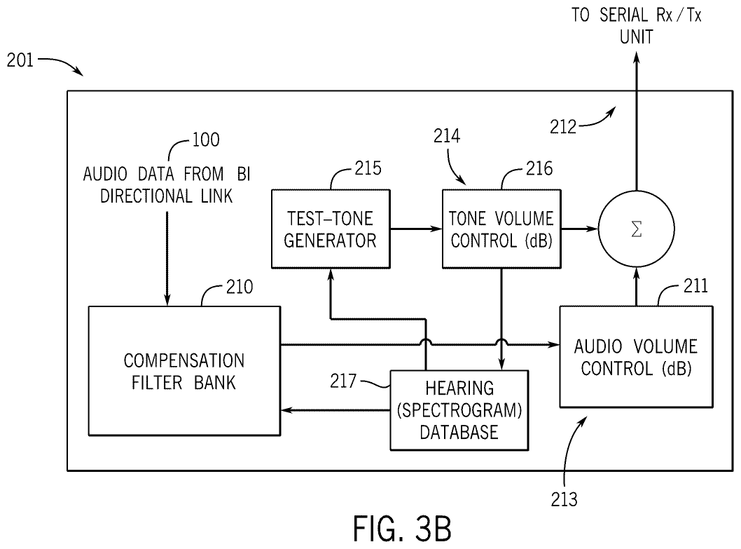

FIG. 1 shows an in-ear audio monitoring system 1 using a bidirectional link 100 in accordance with an exemplary embodiment of the invention. The in-ear audio monitoring system 1 is designed to be used by musicians when practicing or performing. There are three basic elements to the in-ear audio monitoring system 1. A control console 10 with an RF transceiver operated by a sound engineer. The control console 10 can be a rack-mounted mixer or mixer recorder with a display and screens or can be connected to a digital audio workstation as is known in the art. A belt-worn, receiver body pack 200 with an RF transceiver 210 that communicates via tuned UHF or VHF with the control console 10. Two in-ear monitors 300A and 300B, e.g. right side and left side in-ear monitors. The bidirectional link 100 physically connects to the right side and the left side in-ear monitors 300A, 300B to the receiver body pack 200. A jack 105 physically connects one end of the bidirectional link 100 to a port 208 on the receiver body pack 200. Jacks 101A, 101B physically connect the other end of the bidirectional link 100 to ports 308A, 308B on the in-ear monitors 300A, 300B respectively. Although not shown and a non-preferred alternative, the receiver body pack 200 can be configured to have a second audio output port, similar to port 208, in which case one bidirectional link can be physically connected between the receiver body pack 200 and one of the in-ear monitors 300A and another bidirectional link 100B can be physically connected between the receiver body pack 200 and the other in-ear monitor 300B. Multi-channel digital audio data and non-audio data are transmitted over the bidirectional link 100 using time division multiplexed serial data transmission as described in more detail below with respect to FIGS. 3A and 3B. On stage, a multi-channel audio mix is typically transmitted at a selected radio frequency from the rack mounted RF transmitter on the control console 10 to the RF receiver 210 on the receiver body pack 200. Then, the multi-channel audio is converted to a serial digital data stream, along with other control data, which is transmitted over the respective bidirectional link 100 to the in-ear monitors 300A, 300B. Data is also transmitted from the in-ear monitors 300A, 300B to the receiver body pack 200 over the bidirectional link 100, as described in more detail below. For example, as depicted in FIG. 2A, each in-ear monitor 300A, 300B includes a microphone 308 to monitor sound and/or sound energy level exposed to the user's ear canal. The microphone signal is converted to digital serial data in the in-ear monitor 300A, 300B, and is transmitted over the bidirectional link 100 via time division multiplexing. Typically, the in-ear monitoring system 1 will include several receiver body packs 200 and in-ear monitor 300A, 300B pairs, and the control console 10 will transmit the audio mix and otherwise communicate via the several receiver body packs 200. If desired, communication of data or instructions from a given pair of in-ear monitors 300A, 300B and receiver body pack 200 to another receiver body pack and pair of in-ear monitors can occur through RF transmission with the control console 10.

FIG. 2A illustrates components of an example an in-ear monitor 300 is linked to a RF receiver body pack 200 in FIG. 3A via the bidirectional link 100. In FIG. 2A, the in-ear monitor 300 has a soft in-ear flexible housing 306 containing an output port 307. Alternatively, the in-ear monitor can be a molded earpiece. The in-ear monitor 300 has an exterior housing 310 contains electronic components (such as analog signal amplifiers 303A-C and 309), and acoustic output transducers (speakers) 304A-B. A microphone element 308 is mounted to the output port 307 and is configured to be inserted into the base of an ear canal of the user. The larger speaker 304B is efficient at creating lower frequency physical sound waves while the smaller speaker 304A is efficient at producing higher frequency physical sound waves. A haptic actuator 304C is mounted to the exterior housing. The haptic acoustic element is intended to supplement an audio mix, such as providing simulated bass reverberations.

While it is possible that the receiver body pack 200 worn by one performer communicate directly with another receiver body pack worn by another performer in the group, it is expected that the receiver body pack 200 will communicate via RF transmission with a control console or similar audio equipment operated by a sound engineer. In addition to acoustic elements designed to produce a physical acoustic waveform, the audio transducer system 300 may also include one or more microphone elements 308 placed to detect sound levels representing the sound resulting in the ear canal from audio feedback presented to the performer while using this device. In some embodiments, it may be desirable to monitor ambient sound levels being experienced by the user. These levels may be calculated by the FPGA 401 (FIG. 2B) of the transducer processing unit 400. In some embodiments, it may be become desirable that sound levels be remotely adjusted so that the user can perceive a clear representation of the audio signal presented by the acoustic elements 304A-B to their ear canal, while avoiding levels so loud as to produce risk of hearing damage. In some embodiments, there may be cases where a sound engineer may wish to be able to receive (hear) verbal commands provided by the user while performing. In these embodiments, the microphone element 308 in the in-ear housing 307 is placed to enhance detection of the user's voice travelling through the Eustachian tube into the plugged ear canal in order to isolate the detected voice from the eternal (noisy) environment. Subsequently, the microphone output signal 310 is provided as the input to an analog-to-digital converter (ADC) 311 and then to the FPGA or microprocessor 401 of the transducer processing unit 400 for further processing, transmission or analysis, depending on the user's preferences. Since voice commands issued by the user are transmitted back down the bidirectional link 100 to the receiver body pack 200, and subsequently transmitted to the control console 10 (or other device) to it where it may be monitored by a sound technician (or analyzed with speech recognition software). The sound engineer (or software controls) may configure and/or control aspects of the in-ear-monitor including operation of the metronome feature in response to the voice command.

In some embodiments, it may become preferable to locate the microphone element 308 on the exterior housing 310 to allow it to monitor sound levels that are ambient to the user while performing

The earbud insert 306 may be constructed of a flexible silicon compound or soft memory foam in others. Sound waves produced by the output acoustic elements 304A-B waves are mixed through the earbud insert 306 that fits (or protrudes) into the ear canal of a user. In embodiments where the earbud insert 306 is composed of compression (memory) foam, it may naturally expand to fit perfectly (and comfortably) in the user ear canal. Even though this embodiment shows the use of two output acoustic elements 304A-B (apart from the haptic element 304C) in other embodiments, an arbitrary number of output acoustic elements may be preferred. Unlike the prior art, a “frequency divider” circuit is not required, since the shielded bidirectional cable 104 is able to serially transmit multiple distinct audio channels utilizing time-division-multiplexing.

Referring to FIG. 2B, a more detailed diagram for the audio processing unit 400 within the audio transducer 300 is presented. Internal to the audio processing unit 400, The audio processing unit 400 may receive DC power that is superimposed over communications being send through the bidirectional link that is isolated by a power supply isolation circuit 405. In this circuit capacitive coupling allows for serial communications signals generated (or received) by the serial transceiver 402 to be superimposed onto the DC voltage level. The serial audio data is received from the bidirectional link 100 by a serial transceiver 402 where it may be converted to, for example, PCM data streams. The PCM data streams are de-multiplexed by an internal FPGA, DSP, microprocessor or microcontroller 401 into distinct PCM data streams that are presented to a set of digital-to-analog (D/A) converters 403a and 403b. While the exemplary embodiment describes the use of PCM data streams, it is contemplated that the invention could be implemented with audio data streams encoded in other formats than PCM. Subsequently, the analog output 404a and 404b from the D/A converters 403a-b is applied as input to a set of analog amplifiers 302a through 302b, FIG. 2A, respectively for driving the speakers 304a and 304b. The acoustic elements (speakers) 304a and 304b produce a physical waveform in chambers 305a and 305b that propagate through the output port 307 into the ear canal of the user to be heard by the user.

The analog signal 310 from the output of the microphone transducer amplifier 309A (FIG. 2A) is applied to an analog-to-digital converter 311 to produce a data stream that is processed by the FPGA 401 and returned to the audio base unit 200 via the serial transceiver 402 utilizing time-division-multiplexing (TDM) to facilitate bidirectional serial communication. For some embodiments, the word clock may run at a 48 MHz rate. This disclosure also envisions the use of higher word clock rates such as 96 MHz.

The illustrated bidirectional link 100 is a cable with 3.5 mm jacks, however, a wide array of connectors may prove suitable and are envisioned by this disclosure. Referring to FIG. 2A, in the preferred embodiment, the cable portion 104 of the bidirectional link 100 contains at least two conductors: 1) a signal line (i.e the active line connected to tip connector 102 on the jacks 101, 105) carrying bidirectional serial data superimposed on a DC power supply and 2) a ground line connected to the ring connectors 103 on the jacks 101, 105. The ground line 103 can also serve as the cable shielding. Although the use of 3.5 mm headphone jacks is illustrated, a segment of 50 ohm coaxial cable may be serve as the cable portion 104 of the bidirectional link 100, where simple BNC connectors placed at each end may serve as a means to connect the end-point connectors 101 and 105 with the ports 308 and 208 (in this case configured to receive a BNC connector) on the audio transducer 300 and base unit 200 respectively.

Desirably, once a bidirectional link 100 is provided between an audio base unit 200 and transducer processing unit 400, a limited (test) DC supply 205 (FIG. 3A) is superimposed on the active line. An ID resistor 410 (FIG. 2B) in the audio transducer 300 creates an identifiable voltage drop in line 205 (FIG. 3A) that is measured by an analog-to-digital converter (A/D) 204 housed in the audio base unit 200. The value for the detected ID resistor may then be determined and referenced to a library of values to confirm the interoperability of serial communications over the active line 102 of the bidirectional link 100. Once this has been established, the audio transducer processor unit 400 may retrieve a factory programmed ID (along with other settings) from internal non-volatile memory and communicate these to transceiver unit (Rx/Tx) 202 in the audio base unit 200 to be interpreted by a processing unit 201. The audio transducer 300 may additionally transmit (serially) a structure of information to the base unit 200, including information such as the type of transducer 300, its power/based voltage requirements and desired serial protocol for the exchange of audio information such as the number of channels and type of audio (e.g. sample rate, 16, 24 or 32 bit) and/or user settings, etc. In some embodiments, the audio base unit 200 may contain a library of settings to allow it to configure a wide array of audio transducers 300 (or other compatible equipment) after they are connected. In cases when an audio base unit 200 identifies a compatible (and configurable) audio transducer 300, the audio base unit 200 may send a compatibility success message to the audio transducer, causing it to light an externally visible LED 309 to alert the user that the devices (200 and 300) are indeed interoperable via the hardware providing the bidirectional link 100. In these cases, the audio base unit 200 may enable a DC supply voltage of bias voltage (often used by microphones) via an internal array of analog switches 203 controlled by a processing unit 201. In a preferred embodiment, a current limit of 100 mA may be imposed on the supply to protect components in either the based unit 200 or audio transducer 300. Preferably, serial communications between the units 200 and 300 proceeds at 48 MHz in a format that is similar to the Multichannel Audio Digital Interface (MADI), as described by the AES10 standard of the Audio Engineering Society. If serial data from the audio base unit 200 includes a known sequence that is periodically transmitted, a PLL located in the serial Tx/Rx unit 402 of the transducer processing unit 400 of the audio transducer 300 may synchronize itself to it to derive a word-clock signal synchronized to the audio base unit 200. In the preferred embodiment, a green LED 313 (FIG. 2B) visible from an external portion of the audio transducer 300 enclosure may be illuminated to indicate interoperability, while a red (or flashing red) LED 309 may indicate the failure of the devices (200 and 300) to establish bidirectional serial communications. When compatibility is not indicated, the DC power supply or bias voltage may then remain inactive to prevent any damage if connected to an unknown (older) audio transducer 300. At this point, the absence of a green LED 313 (or presence of a flashing red LED) may notify the user that no (potentially damaging) DC voltage or bias voltage has been activated.

The simplicity and flexibility for the type of cable portion 104 and associated connectors 101 and 105 provide further advantages. Users can maintain confidence that the interconnection between audio transducer 300 and base unit 200 will function nominally despite the use of simple, inexpensive, readily available and easy to understand hardware serving as a bidirectional link 100 between the audio these units. Those skilled in the art will understand that aspects of the invention can be implemented if the bidirectional cable 100 is connected permanently to the audio transducer 300, thereby avoiding the need for transducer connector jack 101. For example, the bidirectional cable can be connected permanently to the pair of in-ear monitors 300A, 300B. Or, a segment of bidirectional cable can be connected permanently between the pair of in-ear monitors 300A, 300B (FIG. 1) and a jack on the main segment of the bidirectional cable from the receiver body pack 200 can connect to a port on the segment between the in-ear monitors 300A, 300B.

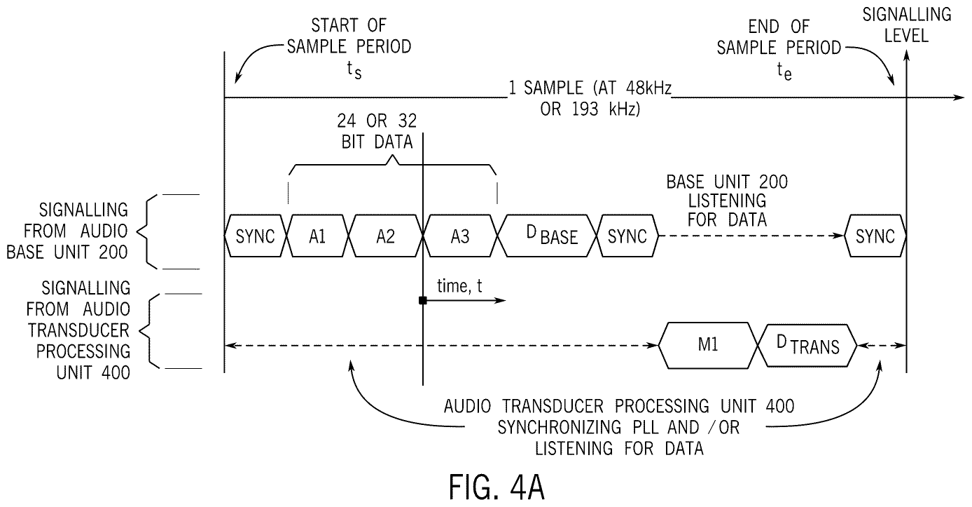

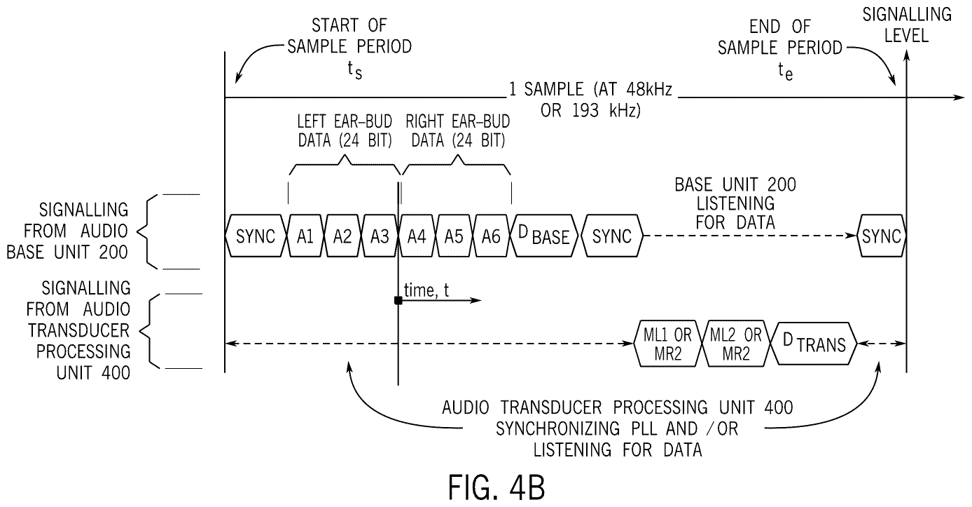

The exemplary embodiment uses half-duplex, bidirectional serial communications over the active line in the bidirectional link 100. A half-duplex serial communications link at each endpoint (200 and 300) of the bidirectional link 100 provides a simpler means for bidirectional communication through a single conductor. In these cases, time-division multiplexing may facilitate bi-directionality of communications across the link 100, by employing time-division-multiplexing between the serial transmitters 202 and 402 in the audio base unit 200 and transducer 300 (that is, within the transducer processing unit 400 of the audio transducer 300), respectively. A timing diagram illustrating the concept is provided in FIG. 4A. This figure illustrates a timing diagram over the span of a single sample period that may correspond to the audio sample period. In many cases, the audio sample rate may be preferably range from Fₛ=48 kHz to Fₛ=192 KHz, and for most embodiments, preferably no less than 8 kHz. In general, an arbitrary audio sample rate (e.g. any value within a continuous supported range) may be selectable (programmable) by the user. In either case, the time spanned between the start of a sample period (as labelled tₛ on the upper left side of FIG. 4A) and the end of a sample period (as labelled tₑ on the upper right side of FIG. 4A) is

$${t}_{e} - {t}_{s} = \frac{1}{{F}_{s}} ( seconds ) .$$

This protocol may be repeated over each sample period where the end-time tₑ for each end of a given sample period corresponds to the start-time tₛ for the next sample period. Signaling activity from the base unit 200 and audio transducer processing unit 400 are labelled on the left side as “Signaling from audio base unit 200” and “Signaling from Audio transducer processing unit 400”, respectively. The signaling over time is readily envisioned by considering the intersection between the vertical line, labelled “time” and the base unit signaling (top waveform in FIG. 4A) and audio transducer signaling (lower waveform in FIG. 4A) waveforms as it progresses from left to right with the passage of time over the sample interval. Initially, at the start of a sampling interval (where t=tₛ), the base unit 200 may emit a predetermined synchronizing word that facilitates lock for a PLL 402 operating in the transducer processing unit 400 of the audio transducer 300 to generate a word-clock reference. The transducer processing unit 400 may then prepare to receive audio data from the base unit 200, starting with the first channel, where a 24- or 32-bit PCM word is denoted by the label “A1” in the diagram. For some embodiments, the use of a different number of bits or a different format (e.g. floating-point) may be preferable. The base unit 200 may then continue to sequentially transmit the audio sample corresponding to each remaining channel “A1” through “A3”, where (for this example three channels are assumed) in general, an arbitrary number of channels may be sequentially sent. Once the transmission of the final audio sample is complete, the base unit may then continue by transmitting device data (as labeled by the packet D_{base} in FIG. 4A). This data may include command settings, environment status, metadata, acknowledgement for the receipt of data (sent earlier) from the transducer processing unit 400 or any other information that it may be desirable for the audio base unit 200 to be able to communicate to the audio transducer 300.

Following the conclusion of any metadata, the base unit 200 may transmit another synchronizing word that may notify the transducer processing unit 400 that it may begin transmitting its audio data (or in some embodiments this may be sound level data) in the desired format, as denoted by “M1” in the diagram. Again, an arbitrary number of channels of data may be sequentially sent by the transducer processing unit 400 (e.g. M1, M2 . . . , etc.). After, the completion for transmission of data from the transducer processing unit 400 (pertaining to the given sample period) to the transceiver 202 within the audio base unit 200, the transducer processing unit 400 may continue by sending a data word (labelled Dₜᵣₐₙₛ in FIG. 3) that includes information related to signal analysis or acknowledgment of changes to device settings for operation of the audio transducer 300. For embodiments where two in-ear monitors 300A, 300B are attached to the bidirectional link 100 as shown in FIG. 1, the data packet D_{base} also desirably contains address data to notify the in-ear monitors 300A, 300B that the receiver body pack 200 is ready to receive monitored sound related data, denoted by ML or MR in FIG. 3B if derived from the left or right in-ear monitors, respectively. Again, an arbitrary number of channels of data may be sequentially sent. For example, if two in-ear monitors 300A, 300B are used as shown in FIG. 1, it may be preferred that the audio base unit 200 toggle requests for audio data between the left and right in-ear monitors from one sample period to the next. In this case, each transducer processing unit 400 (of the left or right in-ear monitor 300A, 300B) sends two data words to represent the two samples, (ML1 and ML2 or MR1 and MR2, respectively) since each will only receive a request for data every other sample period. As shown in FIG. 3B, it may be more convenient to use a protocol where the audio base unit 200 transmits data for all three transducers in both the left and right earbuds during every sample period. In the example in FIG. 3B, data words A1-A3 correspond to transducers 304a-c in the left in-ear monitor, while data words A4-A6 correspond to the transducers 304a-c of the right in-ear monitor. After the completion for transmission of data from the transducer processing unit 400 (pertaining to the given sample period) to the transceiver 202 within the audio base unit 200, the transducer processing unit 400 may continue by sending a data word (labelled Dₜᵣₐₙₛ in FIGS. 3A and 3B) that includes information related to signal analysis or acknowledgment of changes to device settings for operation of the audio transducer system 300. Finally, at the conclusion of this, the base unit 200 may continue by transmitting a final synchronizing signal until the end of the sample period (where t=tₑ) before the system continues with commencing similar operations over the next sample period.

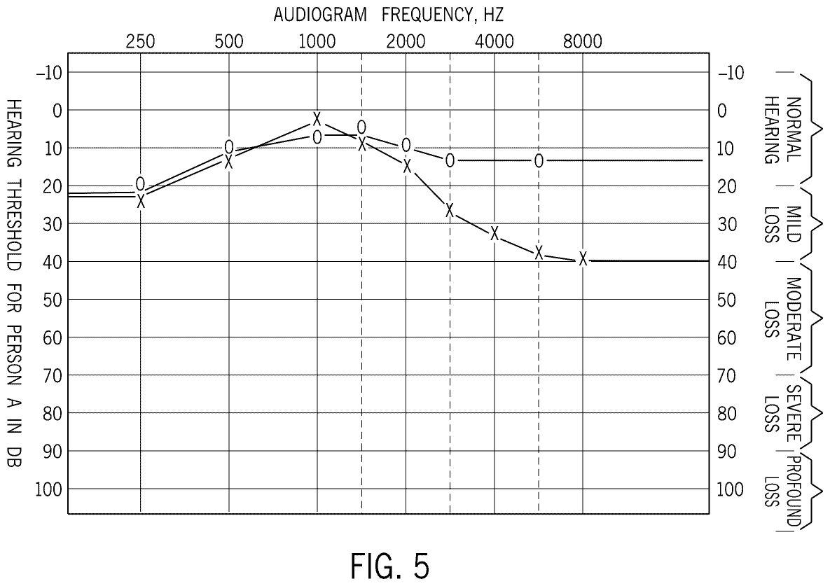

Generally, the hearing sensitivity for an individual (referred to as “person-A”) may be characterized by a chart as shown in FIG. 5 where for a set of frequency points, a minimum (softest sound level) detectable decibel (dB) level is plotted for the right and left ears of the individual. The dB levels referenced here are levels relative to a person with normal hearing. Generally, in the art, diagrams such as the one shown in FIG. 5 are often referred to as “audiograms”. In the audiogram of FIG. 4, the symbols “O” are used for the right ear sensitivity data (measurement) points, while the symbols “X” represents data points for the left ear sensitivity. Typical audiograms provide measurements for a frequency range slightly broader than human speech. To accommodate this, data is often collected at frequencies of: 250 Hz, 500 Hz, 1 kHz, 1.5 kHz, 2 kHz, 3 kHz, 4 kHz, 6 kHz and 8 kHz. The level of hearing loss is indicated by brackets on the far-right hand side of the chart. For example, at 1 KHz, data from FIG. 4 indicates person-A has a left ear threshold of about 2 dB for detectability (normal sensitivity), while person-A's right ear has about a 6 dB threshold (still considered within normal sensitivity) of detectability. These data points are relative and made in reference to a 0 dB level that is considered the lowest threshold of hearing for a normal person (having no hearing damage) while listening in a quiet environment. At 1 KHz, 0 dB corresponds to a power density of approximately 10⁻¹² W/m². It is worth noting that the dB values for hearing threshold along the y-axis on left portion of the chart increase as the position approaches the lower portion of the chart in FIG. 5. In other words, lower data points on this chart indicate an increased hearing deficit. Continuing with this example, FIG. 5 indicates that person-A possesses approximately 40 dB hearing deficit (borderline between mild and moderate hearing loss) for their left ear at higher frequencies (near 8 kHz), while at lower frequencies (near 250 Hz), their hearing sensitivity is more similar (with approximately a 20 dB deficit in common) between their right and left ears. Ideally, for a person with normal (undamaged) hearing, the data plots for the various frequency points will lie near or close (within 20 dB) to the 0 dB line. It is important not to interpret the data of FIG. 5 as representing absolute sound pressure levels (SPL) values where an individual becomes sensitive to a sound for a specific dB level. For example, the right ear data from FIG. 5 indicates a right ear hearing threshold of about 10 dB at 2000 Hz for person-A. In other words, the sensitivity for person-A's right ear hearing is within the zone of normal hearing at 2000 Hz. The hearing threshold is about 13 dB is indicated at the frequencies of 3 kHz, 4 kHz, 6 kHz and 8 kHz, which is still in the sone for normal hearing. Overall, the hearing sensitivity for a given SPL will vary between 0 dB and 20 dB even for a person with normal hearing. There is a hearing deficit for person-A's right ear (“O”) at 250 Hz, where they would require an amplification to detect sounds that person with normal hearing would hear. An important attribute of hearing loss is that it is rarely consistent over the full frequency range for human hearing. In other words, it is rare to measure an audiogram where the data points (appear to) form a level line at some dB value. It is fairly common (especially with age) for individuals to suffer a hearing loss that is pronounced at higher frequencies like the left ear data (X's) shown in the example chart shown of FIG. 5. In many cases, hearing loss may manifest in the form of a frequency notch where for a specific frequency, a person may experience a significant loss in sensitivity, while their sensitivity for other frequencies may remain relatively intact.

Hearing loss remains quite common among our population. According to the Centers for Disease Control and Prevention, hearing loss is the most common preventable work-related injury with about 22 million people in the U.S. being exposed to hazardous levels. While the exact type of hearing loss experienced from one person to the next may vary widely, the effects of noise masking can affect anyone. It should be emphasized that auditory masking can affect both hearing impaired and normal hearing individuals. An example for auditory masking in the frequency domain may be better understood by considering the content of FIG. 5.

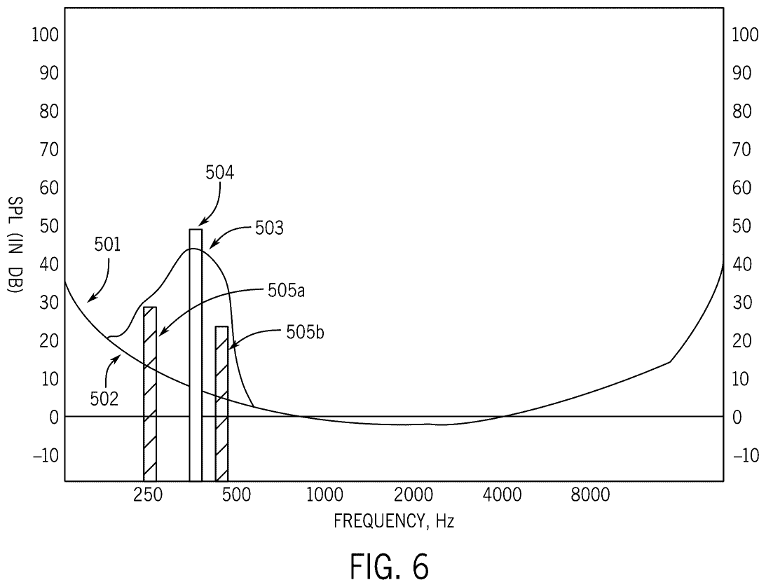

While the data from FIG. 5 is presented in terms of a relative dB offset, the data for FIG. 6 shows data representing a typical threshold of hearing in absolute SPL levels. In this diagram, the curve 501 labeled “(unmasked) Threshold of Hearing” indicates levels that are just detectable by a person with normal hearing. For example, in the range of 2000 Hz to 4000 Hz an individual with normal hearing can just barely detect a sound pressure level of −2 dB SPL. As indicated from this chart, human hearing is the most sensitive in the range of 2000 Hz to 4000 Hz. In contrast, the data point, 502 labeled “(unmasked) Threshold of Hearing at 250 Hz” indicates that a normal person's ear (without masking) will just be able to detect a 250 Hz tone having a level of about 12 dB SPL. Generally speaking, auditory masking refers to how the presence of sound may diminish the perception of other sounds by an individual. In some cases, it may render certain sounds that would otherwise be detectable inaudible to the point where a listener may remain unaware of them. For example, if a “masker” 504 is present (as shown) at approximately 350 Hz, sounds of similar amplitude that are nearby in frequency (as indicated by “Masked Tones” 505a and 505b may be rendered inaudible to a person with normal hearing-even though they are both well above the (unmasked) threshold of hearing for a normal person. From this point of view, the presence of masking sounds may be interpreted as imposing a temporary signal dependent hearing impairment to a listener, regardless of whether they have normal or impaired hearing.

In the event that a sound expert is using a set of in-ear monitors to assess the sound quality for various attributes of a performance, they will inevitably be exposed to a variety of masking sounds (other instruments, crowd, equipment noise, etc.) that combine with any hearing loss they possess that will hinder their ability to assess audio performance (or quality).

When a person having a notch hearing impairment attempts to assess an audio attribute lying in their specific frequency range for hearing loss, they may experience a temptation to increase the volume for an in-ear monitor (in an attempt to render it more perceptible). However, raising the volume also increases the effects of masking sounds-potentially resulting in a cycle where a continuing desire for further improvements in perceptions leads to ever increasing volume settings that ultimately result in an in-ear SPL that is unhealthy for the user. In the worst case, this may create a risk of causing fatigue or hearing loss for their auditory system with long term use and may even lead to users violating standards set by the U.S. Dept. of Labor—Occupational Safety Health Administration (OSHA) for hearing protection.

For example, OSHA standard limits for permissible noise exposure are summarized in Table 1.0 below:

TABLE 1.0
Exposure limits (see: https://www.osha.gov/laws-
regs/regulations/standardnumber/1910/1910.95)

| Maximum permissible | | |
|---|---|---|
| time (hours)/day | Sound Level | |
| 15 minutes | 115 | dB SPL |
| or less | | |
| ½ | 110 | dB SPL |
| 1 | 105 | dB SPL |
| 2 | 102 | dB SPL |
| 3 | 100 | dB SPL |
| 4 | 97 | dB SPL |
| 6 | 95 | dB SPL |
| 8 | 90 | dB SPL |

Embodiments of this invention are envisioned where an in-ear monitor may track the in-ear SPL levels (using microphone 308 FIG. 2A) and cross reference the results to the information of Table 1.0 for the purpose of alerting users if an inappropriate noise exposure risk has been identified.

In this sense, hearing impaired users are at particular risk of attempting to overcompensate with excessive volume levels while attempting to better assess audio performance.

An object of this invention is to compensate the amplitude for an auditory signal over frequency that when presented to the ear of a hearing-impaired user will better approximate the intelligibility that would be achieved if a similar (non-compensated) signal was provided to a normal hearing user. Another object of this invention is to partially compensate for the effects of auditory masking customized to a specific user and environment on an as-needed basis over frequency to further enhance intelligibility. FIG. 3B illustrates how a compensation filter and volume control may be integrated into the signal flow of audio data received from the bidirectional data link 100 by the processor block 201 in the audio base unit 200 from FIG. 3A. As indicated, the user (listener) may adjust the volume level 211 on a dB basis to suit their preferences. In general, turning up the volume level 211 will increase the SNR perceived by the user and correspondingly improve the intelligibility for the user to perceive attributes of the audio signal.

In order to satisfy the objective of compensating for a combination of hearing deficit and auditory masking, an in-situ audiogram may be performed for a user in their working environment. For example, they may choose to perform the audiogram test in the presence of other equipment and/or musical instruments that are intended to be present while the in-ear monitor is to be used. A test tone generator 215 as illustrated in the apparatus of FIG. 3B may be used to superimpose an output test tone of specific amplitude onto the audio signal 212 that is sent to the in-ear monitor. Specifically, when requested by a user, a test tone generator 215 may be activated to supply (or add in) a test tone of amplitude determined by a user-controlled test tone volume adjustment 216. Upon presentation of the tone, a user may then adjust the test tone volume control 216 such that they can just barely perceive the presence of the tone. For some embodiments, it may be advantageous to pulse the tone on and off every 500 ms or so to allow the user to more quickly assess their perception of it. In some (simpler) embodiments, it may be desirable to provide the user with a rotary control knob 216 (encoder) that provides a series of rotational detent positions, where rotating clockwise, increases the tone amplitude by 1 dB for each (detent) click. Similarly, the test tone amplitude may decrease for 1 dB for each counterclockwise rotational (detent) click. When the user is satisfied that their threshold has been reached, they may press the encoder to signal to the hearing (spectrogram) database 217 that the current value indicated by the encoder represents a threshold value that should be stored as part of an audiogram for the frequency of the test tone. This process may proceed from one test frequency to the next until data collection is complete. Since this test may be conducted in the presence of expected auditory masking sources, the user's individual threshold of hearing coupled with their individual response to any auditory masking will be quantified by the volume setting that corresponds to their ability to just hear the presence of the tone. Repeating this process for a predetermined set of frequencies, such as those indicated by FIG. 5 may produce an audiogram that includes auditory masking deficits. Upon completion for collecting an in-situ audiogram, the collected data may be stored by the processor 201 in the database 217 and associated with a user and testing environment. Generally, these may be collected for multiple users and environments and later recalled (upon request by a user) when an in-ear monitor is to be used in a corresponding environment by a specified user. For example, a user may want to quantify audiogram data for later use in a live performance in dependence on the expected size of a crowd, ambience of a stage or theater and/or the presence/use of various musical instruments.

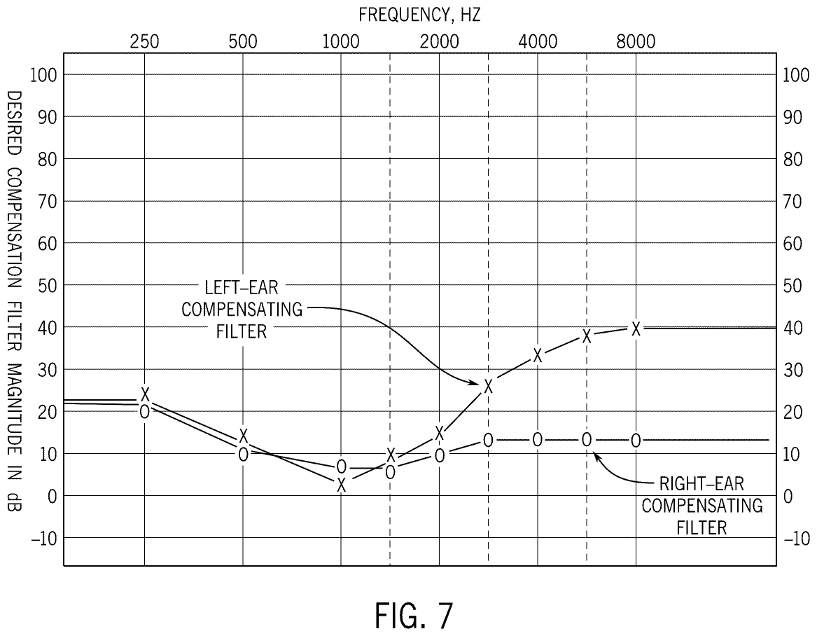

For example, assume that an in-situ audiogram for person-A resulted in the data 217 as displayed in FIG. 5. In order to compensate for the dB deficit at each test frequency, a filter having an inverse gain at each frequency point may be positioned in the base unit processing unit 201 as shown by the processing block 210 (FIG. 3B). While many options exist for designing such a filter, attributes that are generally desirable include low latency and when possible (within latency constraints) linear phase. A well-known window design method may be used to produce a relatively short FIR filter approximating these desired attributes. Inverting the gain at each frequency point in FIG. 5 produces data as shown in FIG. 7. Optimally, a distinct custom designed compensating filter 210 may be designed separately for the right and left ears for a variety of operating environments, based on the corresponding data. Continuing with this example for person-A's left ear, assume a short FIR filter (operating at a sample frequency of F_{S}=48 KHz) is desired for the compensation filter 210 with the following gains as summarized in Table 2.0 (taken from FIG. 7) below:

TABLE 2.0
Gains for optimal (left) filter 210 (data taken from FIG. 7)

| Frequency | Gain |
|---|---|
| (Hz) | Level (dB) |
| 0 | 25 |
| 250 | 25 |
| 500 | 15 |
| 1k | 3 |
| 1.5k | 8 |
| 2k | 15 |
| 3k | 27 |
| 4k | 33 |
| 6k | 37 |
| 8k | 40 |
| Fs/2 = 24k | 40 |

Following the window-based design for an FIR filter, start by setting a normalized frequency and amplitude vectors as

$$f = [ \begin{matrix}0 \\ 0.01014 \\ 0.0208 \\ 0.0417 \\ 0.0625 \\ 0.0833 \\ 0.125 \\ 0.1667 \\ 0.25 \\ 0.333 \\ 1\end{matrix} ] and m = [ \begin{matrix}17.7828 \\ 17.7828 \\ 5.6234 \\ 1.4125 \\ 2.5119 \\ 5.6234 \\ 22.3872 \\ 44.6684 \\ 70.7946 \\ 100 \\ 100\end{matrix} ]$$

The elements of f are obtained from the corresponding frequency data values divided by (F_{S}/2). The gain values of m may be obtained by converting the values from dB into linear gain from Table 2.0. As an example, assume Nₕ=1024 point FFT routine can be implemented in the processor 201 with an FIR filter containing Nₜ=100 taps From these, we can construct a magnitude template by filling an (Nₕ/4+1)×1 vector, ma, where for each element, the magnitude linearly scales between values from m, where the (Nₕ/2+1) indexes are normalized from 0 to F_{S}/2. For this example, we have chosen Nₕ/2=512, we can set ha(1)=17.7828 for the magnitude at zero frequency in f. Similarly, we can set Ha(128)=70.7946

$$( noting that 0.25 * \frac{{N}_{h}}{2} = 128 )$$

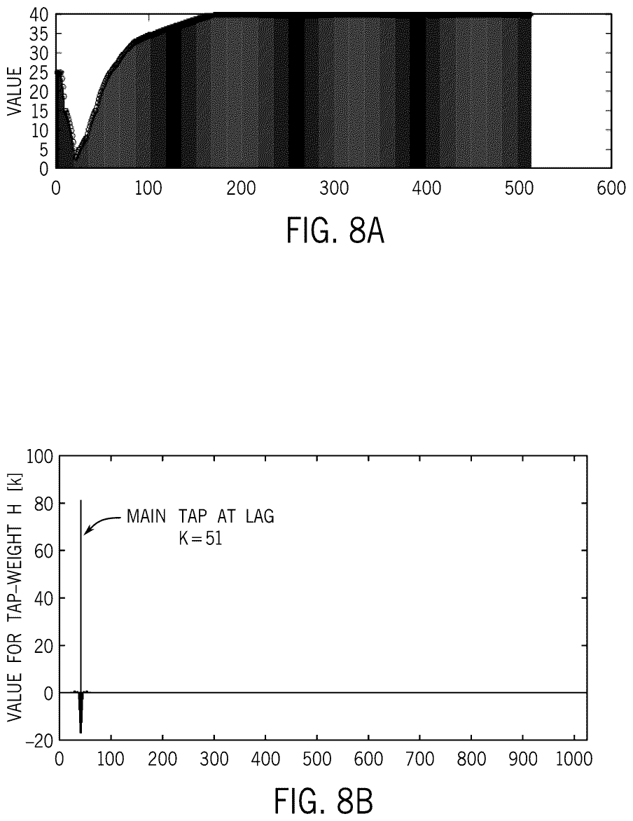

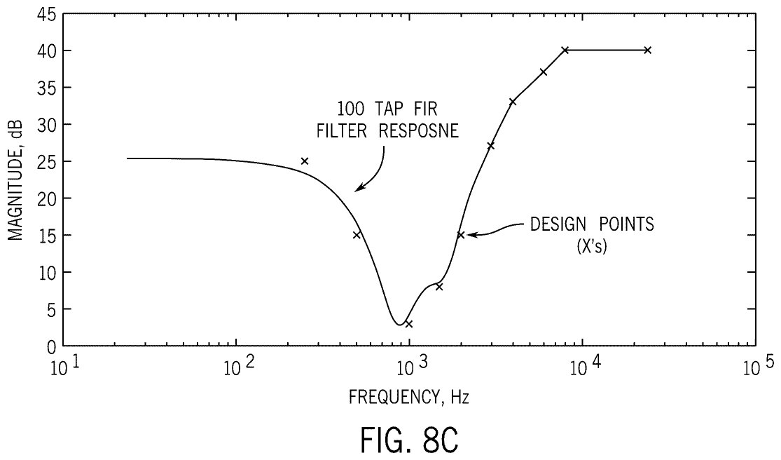

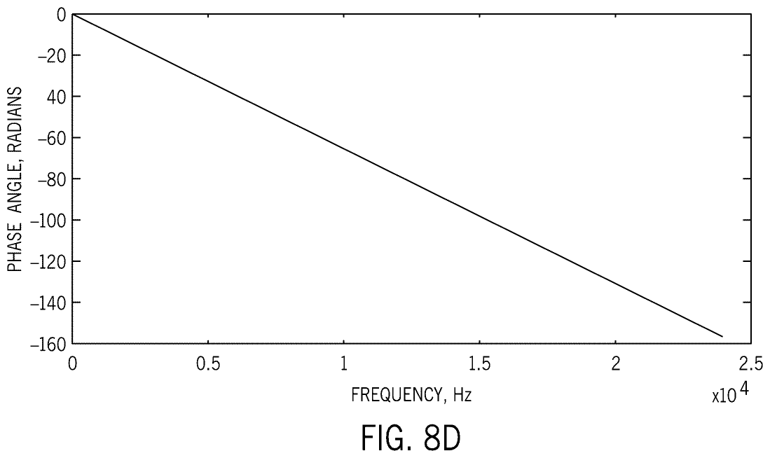

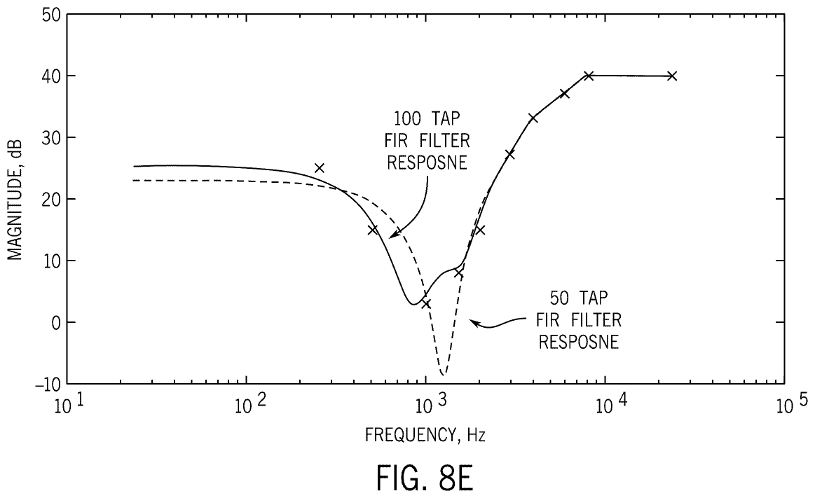

for the frequency point f=0.25 above. These values will then linearly increase to Ha(171)=100 for the frequency point f=0.33 above. Applying this technique across the entirety of the (N+1) indexes for ma, results in the 512×1 amplitude vector plotted in FIG. 8A. The plot of FIG. 7A may be viewed as an amplitude template for the desired frequency response. Generally speaking, taking the inverse transform for an arbitrary collection of points yields complex valued results.

Applying a phase value to each element of Ha can provide for an inverse transform that is both real and causal (by shifting Nₜ/2 indexes to the right in the time domain) by multiplying with the following phase vector, where for all k<Nₕ:

$${H}_{a} ( k ) = {H}_{am} ( k ) {e}^{( \frac{- j ( k - 1 ) {N}_{t} / 2}{{N}_{h}} )}$$

Applying symmetry properties yields a real-valued result by appending a mirror image of Hₐ to construct a 1024×1 complex (frequency-domain) vector, H as:

$$H = [ {H}_{a} ; flip ( conj ( {H}_{a} ) ) ]$$

The flip operation in the above equation reverses the order of the elements across the vector, while the conj function takes the complex conjugate for each value. Applying this to the data from FIG. 8A and taking the inverse (1024 point) FFT results in the FIR filter taps plotted in FIG. 8B.

$$h ( k ) = {FFT}^{- 1} \{ H \}$$

Although this yields (for this example) a 1024 length sequence, most of the meaningful tap values occur near the main pulse at around a lag, k=50, while taps at a significant distance from this lag (k>Nₜ) are very close to zero. A simple window function may serve to simplify the response by trimming off tap values (near the end of the sequence) that will have little impact on the filter output. As a simple example, a rectangular window function may be applied with the following equation where the applied window function (in this case) is a rectangular window

$${h}_{w} ( k ) = h ( k ) w ( k ) , f or k = 1 to 1024$$

$$where w ( k ) = \{ \begin{matrix}1 , & k < {N}_{t} \\ 0 , & k \geq {N}_{t}\end{matrix}$$

Resulting in a 100-tap FIR filter, h_{w}(k) as shown in FIG. 8B.

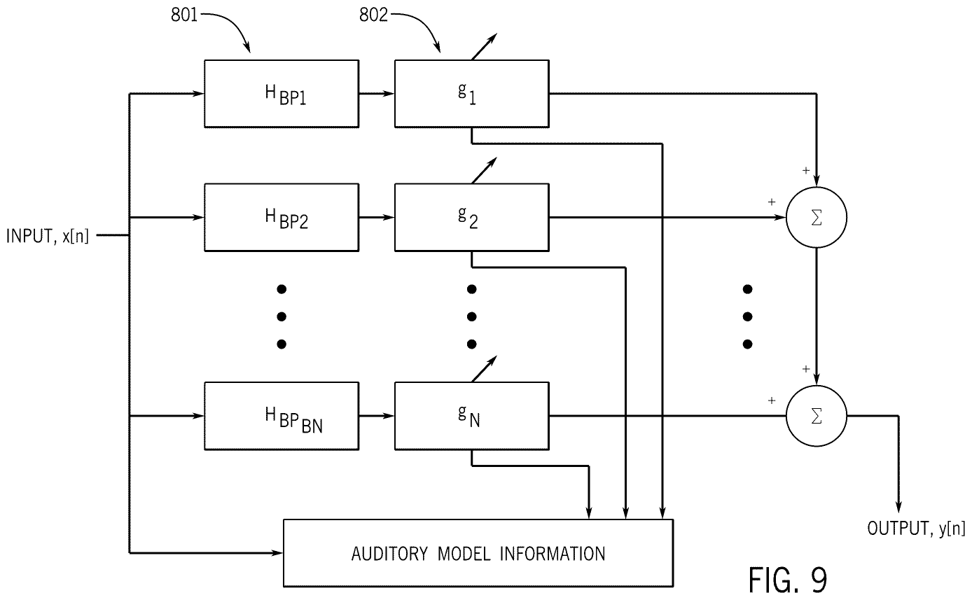

FIG. 8C illustrates the amplitude for the frequency response compared to the original design points (left ear—X's) from FIG. 6. FIG. 8D shows that the phase for the resultant filter is highly linear due to the symmetry (around the “main tap”) of the tap-weight structure illustrated in FIG. 8B. Given a sample rate of F_{S}=48 KHz, this filter will exhibit a latency of only about 1.04 ms. The design methods just described may allow for shorter latency times. However, further reducing latency can cause increasing deviation from the design points and indicates a design trade-off between the accuracy of the compensation filter versus filter length. As a further example, FIG. 8E illustrates a comparison for the effects of setting the number of taps at Nₜ=100 taps (1.04 ms latency) versus Nₜ=50 taps (with 0.502 ms latency). In general, an assortment of window functions may prove useful in the design. An advantage of the rectangular window (used for the examples) is that it typically gives better approximation for the design points. Other popular options for windowing include the Hamming, Boxcar, Hann, Bartlett, Blackman and Kaiser window functions, each having their own advantages. Advanced embodiments are envisioned where users may be allowed to select between differing window functions and/or latency settings for the design of the compensation filter based on their preference. Furthermore, it should be emphasized that embodiments for the compensation filter are by no means limited to an FIR filter-based design, as described above. FIG. 9 provides a compensation filter construction that is based on a series of parallel digital filters 801 that collectively comprise the compensation filter 210 of FIG. 3B. In this arrangement, each band-pass filter (or “filter stage” 801) provides a digital filter having close to a 0 dB gain for a desired frequency point from Table 2.0, while attenuation signal components further from this frequency point. By setting the corresponding “gain stage” 802 to match a desired gain as derived from the audiogram database (217 in FIG. 3B) (or in the previous example from Table 2.0), an overall response may be constructed to closely approximate the desired compensation filter data (such as shown in FIG. 7). In this case, each filter stage may be based on an FIR or IIR design to improve cycle efficiency and minimize latency. The assignee of this application has developed a product, referred to as “Noise Assist” that contains a (Cosine modulated) filter bank that for some embodiments may provide a suitable approach for such a filter bank design.

Although this disclosure has disclosed exemplary embodiments of implementing the invention, alternative configurations are contemplated within the spirit of the invention. For example, each of the “gain stages” of FIG. 9 may be replaced with a band dependent limiter 802 that derives settings in accordance with data from the audiogram database (217 in FIG. 2B) such that hearing limits (like those of Table 1.0) are followed.

1. A multichannel audio system comprising:
a right-side audio transducer element for the user's right ear and a left-side audio transducer element for the user's left ear comprising a pair of earpieces or headphones, the audio transducer element for each ear comprising an audio transducer processing unit, a plurality of transducer amplifiers and a plurality of speakers;
an audio base unit electronically communicating with the right-side audio transducer element for the user's right ear and the left-side audio transducer element for the user's left ear;
a right-side compensation filter element for the right ear that modifies multichannel audio data to drive the speakers in the right-side transducer element in order to account for frequency detected hearing impairment in the right ear and auditory masking conditions in selected acoustic environments the user; and
a left-side compensation filter element for the left ear that modifies multichannel audio data to drive the speakers in the left-side transducer element in order to account for frequency detected hearing impairment in the left ear and auditory masking in selected acoustic environments encountered by the user; and
wherein the audio base unit is configured to output multichannel digital audio data before or after being modified by the right-side compensation filter element and the left-side compensation filter element, and the speakers in the right-side audio transducer element are driven by multichannel digital audio data modified by the right-side compensation filter element and the speakers in the left-side audio transducer element are driven by multichannel digital audio data modified by the left-side compensation filter element.

2. The multichannel audio system as recited in claim 1 wherein coefficients for the right-side compensation filter element and the left-side compensation filter element are stored in non-volatile memory on the right-side transducer element or the left-side side transducer element or both.

3. The multichannel audio system as recited in claim 1 wherein the right-side compensation filter element is located on the right-side transducer element and left-side compensation filter element is located on the left-side transducer element.

4. The multichannel audio system as recited in claim 1 wherein the right-side compensation filter element and left-side compensation filter element are located on the audio base unit.

5. The multichannel audio system as recited in claim 1 wherein the audio base unit further comprises a test-tone generator, a volume control for the test tone generator, and a spectrogram database for storing hearing test data taken with the test tone generator.

6. The multichannel audio system as recited in claim 5 wherein the compensation filter elements are derived from test-tone data stored in the spectrogram database.

7. The multichannel audio system as recited in claim 4 wherein the compensation filters are two of multiple compensation filters for the user selected for the auditory masking conditions in which user expects to be using the audio transducer element.

8. The multichannel audio system as recited in claim 5 wherein the audio base unit also comprises an audio volume control for the multichannel digital audio data, and the test tones from the test-tone generator and the test tone volume control are summed in the multichannel digital audio data after the volume for the multichannel digital audio data has been set.

9. The multichannel audio system as recited in claim 1 wherein the audio transducer element for each ear further comprises a microphone that outputs an analog signal, a microphone signal amplifier, an analog-to-digital converter in the transducer processing unit that receives an amplified analog microphone signal from the microphone signal amplifier, wherein the audio transducer processing unit is configured to receive amplified analog microphone signal and output digital microphone data that is transmitted to the audio base unit.

10. The multichannel audio system as recited in claim 9 wherein the microphone for each ear is adapted to be placed to be in the ear canal and the generated microphone signal represents the sound pressure level in the ear canal.

11. The multichannel audio system as recited in claim 1 wherein each audio transducer element is an earbud comprising:
an exterior housing, and said plurality of acoustic elements includes a first acoustic transducer and a second acoustic transducer;
an in-ear plug housing that is configured to be placed in the ear canal of the user, said interior housing having an acoustic output port; and
a first acoustic chamber extending from the first acoustic transducer in the exterior housing into the in-ear pug housing and a second acoustic chamber extending from the second acoustic transducer in the exterior housing into the in-ear plug housing.

12. The multichannel audio system as recited in claim 11 wherein each earbud further comprises a microphone in or adjacent to the acoustic output port of the in-ear plug housing and generates a microphone signal that is processed and transmitted to the audio base unit.

13. The multichannel audio system as recited in claim 1 further wherein the compensation filter elements are FIR filters or IIR filters.

14. The multichannel audio system as recited in claim 1 further wherein the compensation filter elements each comprise a series of digital filters having a bandpass filtering stage and a gain stage.

15. The multichannel audio system of claim 1 further comprising:
a bidirectional connecting cable connecting the right-side transducer element and the left-side transduce element to a port the audio base unit;
wherein the bidirectional connecting cable has an active line and a ground line, and data is transmitted bidirectionally over the active line as time-division multiplexed serial data words.

16. The multichannel audio system as recited in claim 15 wherein the left-side audio transducer processing unit and the right-side audio transducer unit each comprise:
a. an internal digital processor that de-multiplexes multichannel digital audio data and non-audio data transmitted to the respective audio transducer processing unit and outputs separate digital audio signals for each speaker on the respective audio transducer element; and
b. multiple digital-to-analog converters for the speakers, each receiving one of the separate digital audio signals and outputting an analog audio signal for each speaker on the respective audio transducer element.

17. The multichannel audio system as recited in claim 12 wherein the user is able to operate to select compensation filter elements using voice commands.

18. The multichannel audio system as recited in claim 15 wherein the audio base unit has an RF receiver or transceiver to receive digital audio data and non-audio data wirelessly from an RF transmitter of a control console.
